(19) United States
(12) Patent Application Publication
(10) Pub. No.: US 2025/0040382 A1
(43) Pub. Date: Jan. 30, 2025

(54) DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventors: Hongyan LIU, Wuhan (CN); Feixiang SUN, Wuhan (CN)

(21) Appl. No.: 18/915,510

(22) Filed: Oct. 15, 2024

Related U.S. Application Data
(63) Continuation of application No. 17/771,481, filed on Apr. 24, 2022, now Pat. No. 12,161,032.

(30) Foreign Application Priority Data
Mar. 4, 2022 (CN) 202210208967.3

(51) Int. Cl. H10K 59/131

(52) U.S. Cl. CPC H10K 59/131

(57) ABSTRACT

The present disclosure discloses a display panel in which a second data line in a display area is located between a first data line and a third data line, and a spacing between the first data line and the second data line is less than a spacing between the third data line and the second data line. A second pad is located between a first pad and a third pad in a direction perpendicular to the display area pointing to a binding area, the first pad is electrically connected to the first data line, the second pad is electrically connected to the third data line, and the third pad is electrically connected to the second data line.

### CROSS-REFERENCE TO RELATED APPLICATIONS

This application is a continuation application of U.S. application Ser. No. 17/771,481, filed on Apr. 24, 2022, which is a National Phase of PCT Patent Application No. PCT/CN2022/081418 having international filling date of Mar. 17, 2022, which claims the priority of Chinese Application No. 202210208967.3 filed with the Chinese Patent Office on Mar. 4, 2022 and titled “DISPLAY PANEL”, which is incorporated herein by reference in its entirety.

### TECHNICAL FIELD

The present disclosure relates to a technical field of display, and in particular, to a display panel.

### BACKGROUND

At present, when a plurality of data lines are disposed at unequal intervals in a display area of a display panel, a parasitic capacitance between two data lines that are close to each other is inconsistent with a parasitic capacitance between two data lines that are far away, which will affect display effects of a display panel.

Therefore, it is necessary to provide a technical solution to solve a problem that inconsistency of parasitic capacitances between data lines affecting display effects.

### Technical Problem

The present disclosure aims to provide a display panel to solve a problem that inconsistency of parasitic capacitances among a plurality of data lines affecting display effects.

### Technical Solutions

Provided is a display panel, the display panel has a display area and a binding area, and the display panel includes:
a first data line, a second data line and a third data line extending from the display area to the binding area a first pad, a second pad and a third pad disposed in the binding area;
and a source driver chip;
wherein in the display area, the first data line is electrically connected to a first column of sub-pixels of the display area; the second data line is electrically connected to a second column of sub-pixels the third data line is electrically connected to a third column of sub-pixels; the second data line is located between the first data line and the third data line, and a spacing between the first data line and the second data line is less than a spacing between the third data line and the second data line; the second column of sub-pixels is located between the first column of sub-pixels and the third column of sub-pixels; and
wherein the source driver chip is connected to the first pad, the second pad, and the third pad.

### TECHNICAL EFFECTS

The present disclosure discloses a display panel. In a display area of the display panel, a second data line is located between a first data line and a third data line, and a spacing between the first data line and the second data line is less than a spacing between the third data line and the second data line. In this way, a spacing between the first data line and the second data line in an area between the display area and the binding area is increased and a spacing between the second data line and the third data line is decreased, and therefore a parasitic capacitance between the first data line and the second data line and a parasitic capacitance between the second data line and the third data line tend to be consistent.

### BRIEF DESCRIPTION OF THE DRAWINGS

FIG. 1 is a schematic diagram of a display panel according to some embodiments of the present disclosure;

FIG. 2 is a partial plan view of the display panel shown in FIG. 1;

FIG. 3 is a schematic diagram of a pixel circuit of a sub-pixel of the display panel shown in FIG. 1;

FIG. 4 is a schematic diagram of connection between a pixel circuit of a sub-pixel and a data line of the display panel shown in FIG. 2;

FIG. 5 is a schematic cross-sectional view of the display panel shown in FIG. 1; and

FIGS. 6A-6J are schematic diagrams of film stacking of a pixel circuit of a sub-pixel shown in FIG. 3 and a plurality of signal lines connected to the pixel circuit.

### DETAILED DESCRIPTION

Hereinafter, technical solution in embodiments of the present disclosure will be clearly and completely described with reference to the accompanying drawings in embodiments of the present disclosure. Apparently, the described embodiments are part of, but not all of, the embodiments of the present disclosure. All the other embodiments, obtained by a person with ordinary skill in the art on the basis of the embodiments in the present disclosure without expenditure of creative labor, belong to the protection scope of the present disclosure.

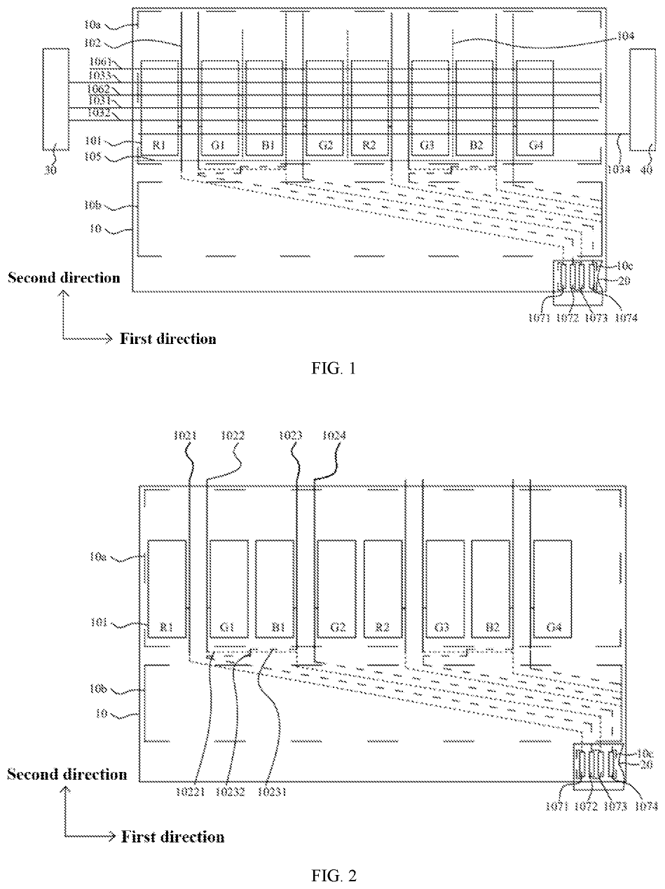

Referring to FIG. 1, the present disclosure provides a display device 50. The display device 50 may be any one of a liquid crystal display device, an organic light emitting diode display device, a micro light emitting diode display device, and a sub-millimeter light emitting diode display device. Specifically, the display device 50 is an organic light emitting diode display device.

The display device 50 includes a display panel 10, a source driver chip 20, a gate driver circuit 30, and a light-emitting control driver circuit 40.

The display panel 10 has a display area 10a, a sector 10b and a binding area 10c. The sector 10b is located between the display area 10a and the binding area 10c in a second direction, and the second direction is a direction from the display area 10a to the binding area 10c.

The display panel 10 includes a plurality of sub-pixels 101, a plurality of data lines 102, a first scanning signal line 1031, a second scanning signal line 1032, a third scanning signal line 1033, a light-emitting control signal line 1034, a first power supply voltage line 104, a second power supply voltage line 105, a first initialization voltage line 1061, a second initialization voltage line 1062, and a plurality of pads.

A plurality of sub-pixels 101 are arrayed in a display area 10a of the display panel along a row direction (first direction) and a column direction (second direction). The plurality of sub-pixels 101 include red sub-pixels, blue sub-pixels, and green sub-pixels, which are disposed in Pentile RGB.

The plurality of pixels 101 include a first red sub-pixel R1, a first green sub-pixel G1, a first blue sub-pixel B1, a second green sub-pixel G2, a second red sub-pixel R2, a third green sub-pixel G3, a second blue sub-pixel B2, and a fourth green sub-pixel G4 which are disposed in sequence along the first direction in the same row, and the first direction is perpendicular to the second direction. The first red sub-pixel R1, the first green sub-pixel G1, the first blue sub-pixel B1, and the second green sub-pixel G2 serve as a repeating unit, the second red sub-pixel R2, the third green sub-pixel G3, the second blue sub-pixel B2, and the fourth green sub-pixel G4 serve as another repeating unit, and a plurality of repeating units are repeatedly disposed in the row direction.

It can be understood that the red sub-pixels, the blue sub-pixels, and the green sub-pixels may be disposed in a standard RGB, and a plurality of sub-pixels 101 may further include white sub-pixels.

The first scanning signal line 1031, the second scanning signal line 1032, the third scanning signal line 1033, the light-emitting control signal line 1034, the first initialization voltage line 1061, and the second initialization voltage line 1062 are disposed in the display area 10a and extend along the first direction. One first scanning signal line 1031, one second scanning signal line 1032, one third scanning signal line 1033, one light-emitting control signal line 1034, one first initialization voltage line 1061, and one second initialization voltage line 1062 pass through one row of sub-pixels 101 in the row direction.

The gate driver circuit 30 is electrically connected to the first scanning signal line 1031, the second scanning signal line 1032, and the third scanning signal line 1033. The gate driver circuit 30 outputs a first scanning signal Pscan (n), a second scanning signal Nscan (n) and a third scanning signal Nscan (n+1) to the first scanning signal line 1031, the second scanning signal line 1032, and the third scanning signal line 1033, respectively.

The light-emitting control driver circuit 40 is connected to the light-emitting control signal line 1034, and outputs a light-emitting control signal EM to the light-emitting control signal line 1034.

The first initialization voltage line 1061 and the second initialization voltage line 1062 may obtain corresponding signals from an external voltage source. The first initialization voltage line 1061 is used to transmit a first initialization voltage Vi1. The second initialization voltage line 1062 is used to transmit a second initialization voltage Vi2.

A plurality of the first power supply voltage lines 104 are disposed in the display area 10a and extend along the second direction, and one of first power supply voltage lines 104 is disposed between two adjacent data lines 102. The second power supply voltage line 105 is located in the display area 10a and disposed along an edge of the display area 10a.

The first power supply voltage lines 104 and the second power supply voltage lines 105 may obtain corresponding signals from an external voltage source. The first power supply voltage line 104 is configured to transmit a first power supply voltage VDD, which is a predetermined high-level voltage. The second power supply voltage line 105 is used to transmit a second power supply voltage VSS, which is a predetermined low-level voltage.

A plurality of pads are disposed side by side in the binding area 10c along the first direction. The source driver chip 20 is bound to the plurality of pads, and the plurality of pads are electrically connected to the plurality of data lines 102 one to one. The source driver chip 20 outputs a data signal DATA to the plurality of data lines 102 through the plurality of pads.

The plurality of pads include a first pad 1071, a second pad 1072, a third pad 1073, and a fourth pad 1074. The second pad 1072 is located between the first pad 1071 and the third pad 1073. The fourth pad 1074 is located on one side of the third pad 1073 away from the second pad 1072.

Referring to FIG. 2, the plurality of data lines 102 extend from the display area 10a through the sector region 10b along the second direction to be electrically connected to the plurality of pads of the binding area 10c, and the plurality of data lines 102 are insulated from each other. The plurality of data lines 102 includes a first data line 1021, a second data line 1022, a third data line 1023, and a fourth data line 1024. The second data line 1022 and the third data line 1023 are located between the first data line 1021 and the fourth data line 1024. The first pad 1071 is located on one side of the second data line 1022 and the third data line 1023 close to the first data line 1021.

In the display area 10a, the second data line 1022 is loated between the first data line 1021 and the third data line 1023, the fourth data line 1024 is loated on one side of the second data line 1022 and the third data line 1023 away from the first data line 1021, and a spacing between the fourth data line 1024 and the third data line 1023 is equal to a spacing between the first data line 1021 and the second data line 1022.

In the display area 10a, the first data line 1021 is electrically connected to a first column of sub-pixels of the display area 10a, the second data line 1022 is electrically connected to a second column of sub-pixels of the display area 10a, the third data line 1023 is electrically connected to a third column of sub-pixels of the display area 10a, and the fourth data line 1024 is electrically connected to a fourth column of sub-pixels of the display area 10a, the second column of sub-pixels is located between the first column of sub-pixels and the third column of sub-pixels, and the fourth column of sub-pixels is located on one side of the third column of sub-pixels away from the second column. The first column of sub-pixels includes a first red sub-pixel R1, the second column of sub-pixels includes a first green sub-pixel G1, the third column of sub-pixels includes a first blue sub-pixel B1, and the fourth column of sub-pixels includes a second green sub-pixel G2.

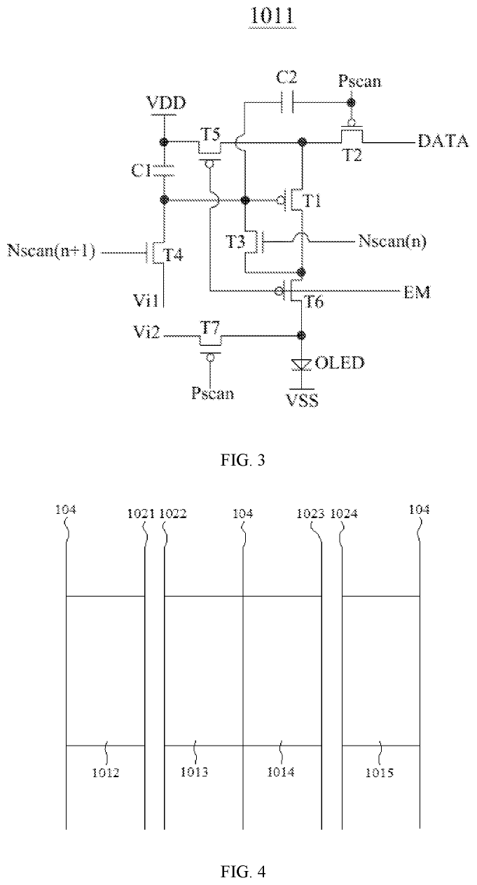

Referring to FIG. 3, each sub-pixel 101 includes a pixel circuit 1011, and each pixel circuit 1011 includes an organic light-emitting diode OLED, a plurality of transistors T1 to T7, and capacitors C1 to C2. One pixel circuit 1011 is input with a data signal DATA, a first scanning signal Pscan, a second scanning signal Nscan (n), a third scanning signal Nscan (n+1), a light-emitting control signal EM, a first power supply voltage VDD, a second power supply voltage VSS, a first initialization voltage Vi1, and a second initialization voltage Vi2.

An organic light-emitting diode OLED includes an anode, a cathode, and an organic light-emitting layer located between the anode and the cathode. The cathode of the organic light-emitting diode OLED is connected to the second power supply voltage VSS.

The first capacitor C1 includes a first electrode plate and a second electrode plate. The first electrode plate of the first capacitor C1 is connected to a gate of the first transistor T1, a first electrode of the third transistor T3, and a first electrode of the fourth transistor T4. The second electrode plate of the first capacitor C1 is connected to the first power supply voltage VDD.

The second capacitor C2 includes a third electrode plate and a fourth electrode plate. The third electrode plate of the second capacitor C2 is connected to the gate of the first transistor T1, the first electrode of the third transistor T3, and the first electrode of the fourth transistor T4. The fourth electrode plate of the second capacitor C2 is connected to the first scanning signal Pscan.

Each of the plurality of transistors T1 to T7 includes a gate, a first electrode, and a second electrode. The first electrode of the plurality of transistors T1 to T7 is one of source or drain, and the second electrode of the plurality of transistors T1 to T7 is the other of source and drain.

The plurality of transistors T1 to T7 are all thin film transistors. Each of the transistors T1 to T7 may be any one of PMOS transistors and NMOS transistors, and an active layer of each of the transistors T1 to T7 is any one of polysilicon and metal oxide.

Specifically, the first transistor T1, the second transistor T2, the fifth transistor T5, the sixth transistor T6, and the seventh transistor T7 are all PMOS transistors. The active layers of the first transistor T1, the second transistor T2, the fifth transistor T5, the sixth transistor T6, and the seventh transistor T7 are all located in a first semiconductor layer, and the first semiconductor layer is a low-temperature polysilicon active layer. Both the third transistor T3 and the fourth transistor T4 are NMOS transistors, and the active layers of the third transistor T3 and the fourth transistor T4 are located in a second semiconductor layer, and the second semiconductor layer is a metal oxide active layer.

It should be noted that characteristics of the PMOS transistors and the NMOS transistors are different from each other. The third transistor T3 and the fourth transistor T4 are formed of an NMOS transistor with relatively good turn-off characteristics, so that leakage of driving current can be reduced during light-emitting period of the organic light emitting diode OLED.

The gate of the first transistor T1 is connected to the first electrode plate of the first capacitor C1, the third electrode plate of the second capacitor C2, the first electrode of the third transistor T3, and the first electrode of the fourth transistor T4. The first electrode of the first transistor T1 is connected to the first supply voltage VDD through the fifth transistor T5, and the first electrode of the first transistor T1 is connected to the data signal DATA through the second transistor T2. The second electrode of the first transistor T1 is connected to an anode of the organic light-emitting diode OLED through the sixth transistor T6. The first transistor T1 receives the data signal DATA according to a switching operation of the second transistor T2, and supplies a driving current to the organic light-emitting diode OLED.

The gate of the second transistor T2 is connected to the first scanning signal Pscan. The first electrode of the second transistor T2 is connected to the data signal DATA. The second electrode of the second transistor T2 is connected to the first electrode of the first transistor T1, and the second electrode of the second transistor T2 is connected to the first supply voltage VDD through the fifth transistor T5. The second transistor T2 is turned on in response to the first scanning signal Pscan to perform a switching operation of transmitting the data signal DATA to the first electrode of the first transistor T1.

The gate of the third transistor T3 is connected to the second scanning signal Nscan (n). The first electrode of the third transistor T3 is connected to the first electrode of the fourth transistor T4 and the gate of the first transistor T1, and the second electrode of the third transistor T3 is connected to the second electrode of the first transistor T1 and the first electrode of the sixth transistor T6. The third transistor T3 is turned on in response to the second scanning signal Nscan (n) to connect the gate and the second electrode of the first transistor T1, thereby diode-connecting the first transistor T1. A voltage difference is generated between the gate electrode of the first transistor T1 and the second electrode by a threshold voltage of the first transistor T1, and a data signal DATA having a compensated threshold voltage is supplied to the gate of the first transistor T1, thereby compensating threshold voltage deviation of the first transistor T1.

The gate of the fourth transistor T4 is connected to the third scanning signal Nscan (n+1). The first electrode of the fourth transistor T4 is connected to the gate of the first transistor T1, the first electrode plate of the first capacitor C1, the third electrode plate of the second capacitor C2, and the first electrode of the third transistor T3. The second electrode of the fourth transistor T4 is connected to the first initialization voltage Vi1. The fourth transistor T4 is turned on in response to the third scanning signal Nscan (n+1) to output the first initialization voltage Vi1 to the gate of the first transistor T1 to perform an operation of initializing voltage of the gate of the first transistor T1.

The gate of the fifth transistor T5 is connected to the light-emitting control signal EM, the first electrode of the fifth transistor T5 is connected to the first supply voltage VDD, and the second electrode of the fifth transistor T5 is connected to the first electrode of the first transistor T1 and the second electrode of the second transistor T2.

The gate of the sixth transistor T6 is connected to the light-emitting control signal EM, the first electrode of the sixth transistor T6 is connected to the second electrode of the first transistor T1 and the second electrode of the third transistor T3, and the second electrode of the sixth transistor T6 is connected to an anode of the organic light emitting diode OLED and the first electrode of the seventh transistor T7.

The gate of the seventh transistor T7 is connected to the first scanning signal Pscan, the first electrode of the seventh transistor T7 is connected to an anode of the organic light-emitting diode OLED and the second electrode of the sixth transistor T6, and the second electrode of the seventh transistor T7 is connected to the second initialization voltage Vi2. The seventh transistor T7 is turned on in response to the first scanning signal Pscan to transmit the first scanning signal Pscan to the anode of the organic light-emitting diode OLED, thereby realizing initialization of the anode of the organic light-emitting diode OLED.

Referring to FIG. 4, the first red sub-pixel R1 includes a first pixel circuit 1012, and the first pixel circuit 1012 is electrically connected to the first data line 1021. The first green sub-pixel G1 includes a second pixel circuit 1013, and the second pixel circuit 1013 is electrically connected to the second data line 1022. The first blue sub-pixel B1 includes a third pixel circuit 1014, and the third pixel circuit 1014 is electrically connected to the third data line 1023. The second green sub-pixel G2 includes a fourth pixel circuit 1015, and the fourth pixel circuit 1015 is electrically connected to the fourth data line 1024.

In the display area 10a, at least a portion of the first pixel circuit 1012 is located on one side of the first data line 1021 away from the second data line 1022, at least a portion of the second pixel circuit 1013 and at least a portion of the third pixel circuit 1014 are located between the second data line 1022 and the third data line 1023, and at least a portion of the fourth pixel circuit 1015 is located on one side of the fourth data line 1024 away from the third data line 1023.

Specifically, the first pixel circuit 1012 is divided into a first portion and a second portion. An area occupied by the second portion of the first pixel circuit 1012 is greater than an area occupied by the first portion of the first pixel circuit 1012. The first portion of the first pixel circuit 1012 overlaps the first data line 1021. The second portion of the first pixel circuit 1012 is located on one side of the first data line 1021 away from the second data line 1022. Therefore, the first pixel circuit 1012 is mainly located on one side of the first data line 1021 away from the second data line 1022.

The second pixel circuit 1013 is also divided into a first portion and a second portion. An area occupied by the second portion of the second pixel circuit 1013 is greater than an area occupied by the first portion of the second pixel circuit 1013, the first portion of the first pixel circuit 1012 is the same as the first portion of the second pixel circuit 1013, and the second portion of the second pixel circuit 1013 is the same as the second portion of the first pixel circuit 1012. A first portion of the second pixel circuit 1013 overlaps the second data line 1022, and the second portion of the second pixel circuit 1013 is located on one side of the second data line 1022 away from the first data line 1021. The first pixel circuit 1012 and the second pixel circuit 1013 are disposed symmetrically about a center line between the first data line 1021 and the second data line 1022.

The third pixel circuit 1014 is also divided into a first portion and a second portion. The first portion of the third pixel circuit 1014 is the same as the first portion of the second pixel circuit 1013, the second portion of the third pixel circuit 1014 is the same as the second portion of the second pixel circuit 1013, and an area occupied by the second portion of the third pixel circuit 1014 is greater than an area occupied by the first portion of the third pixel circuit 1014. The first portion of the third pixel circuit 1014 is disposed to overlap the third data line 1023, and the second portion of the third pixel circuit 1014 is disposed adjacent to the second portion of the second pixel circuit 1013 and disposed between the second data line 1022 and the third data line 1023. The second pixel circuit 1013 and the third pixel circuit 1014 are disposed symmetrically about a center line between the second data line 1022 and the third data line 1023. The second pixel circuit 1013 and the third pixel circuit 1014 share a first power supply voltage line 104, and the second pixel circuit 1013 and the third pixel circuit 1014 share a first power supply voltage line 104 located between the second data line 1022 and the third data line 1023.

The fourth pixel circuit 1015 is also divided into a first portion and a second portion. An area occupied by the second portion of the fourth pixel circuit 1015 is greater than an area occupied by the first portion of the fourth pixel circuit 1015. The first portion of the fourth pixel circuit 1015 is the same as the first portion of the third pixel circuit 1014, and the second portion of the fourth pixel circuit 1015 is the same as the second portion of the third pixel circuit 1014. A first portion of the fourth pixel circuit 1015 is disposed to overlap the fourth data line 1024, and a second portion of the fourth pixel circuit 1015 is located on one side of the fourth data line 1024 away from the third data line 1023. The fourth pixel circuit 1015 and the third pixel circuit 1014 are disposed symmetrically about a center line between the third data line 1023 and the fourth data line 1024.

Since each pixel circuit 1011 includes a P-type transistor and an N-type transistor, two different types of scanning signals need to be input to the P-type transistor and the N-type transistor, which results in a complex trace in each pixel circuit, and space required for multiple pixel circuit arrangements is reduced by a mirror symmetrical arrangement between adjacent pixel circuits.

It can be understood that all portions of one second pixel circuit 1013 and all portions of one third pixel circuit 1014 may also be located between the second data line 1022 and the third data line 1023, and all portions of a first pixel circuit 1012 are located on one side of the first data line 1021 away from the second data line 1022, and all portions of one fourth pixel circuit 1015 are located on one side of the fourth data line 1024 away from the third data line 1023.

Due to arrangement of the pixel circuits and the data lines as shown in FIG. 4, a spacing between the first data line 1021 and the second data line 1022 in the display area is less than a spacing between the third data line 1023 and the second data line 1022, and a spacing between the fourth data line 1024 and the third data line 1023 is less than a spacing between the third data line 1023 and the second data line 1022.

The spacing between the first data line 1021 and the second data line 1022 is different from the spacing between the third data line 1023 and the second data line 1022, and the spacing between the third data line 1023 and the second data line 1022 is different from the spacing between the fourth data line 1024 and the third data line 1023, resulting in that parasitic capacitances between the first data line 1021 and the second data line 1022 are different from parasitic capacitances between the third data line 1023 and the second data line 1022. Further, parasitic capacitances between the third data line 1023 and the second data line 1022 are different from parasitic capacitances between the fourth data line 1024 and the third data line 1023. That is, parasitic capacitances between adjacent data lines are inconsistent, which affects display effects of the display panel.

In view of the problem of inconsistent parasitic capacitances between adjacent data lines, in the present disclosure, the first data line 1021 is electrically connected to the first pad 1071, the second pad 1072 is electrically connected to the third data line 1023, the third pad 1073 is electrically connected to the second data line 1022, and the fourth pad 1074 is electrically connected to the fourth data line 1024, so as to facilitate that the spacing between the first data line 1021 and the second data line 1022 in an area between the display area 10a and the binding area 10c is greater than the spacing between the second data line 1022 and the third data line 1023, and the spacing between the fourth data line 1024 and the third data line 1023 is greater than the spacing between the third data line 1023 and the second data line 1022, so that the parasitic capacitances between the first data line 1021 and the second data line 1022, the parasitic capacitances between the second data line 1022 and the third data line 1023, and the parasitic capacitances between the third data line 1023 and the fourth data line 1024 tend to be consistent, thereby ensuring display effects of the display panel.

Specifically, as shown in FIG. 2, the third data line 1023 intersects with the second data line 1022 in an area between the sector 10b and the display area 10a, and the third data line 1023 in the sector 10b is located between the second data line 1022 and the first data line 1021, so that the second pad 1072 is electrically connected to the third data line 1023, and the third pad 1073 is electrically connected to the second data line 1022, thus the spacing between the first data line 1021 and the second data line 1022 in the sector 10b is greater than the spacing between the second data line 1022 and the third data line 1023, and the spacing between the third data line 1023 and the fourth data line 1024 is greater than the spacing between the third data line 1023 and the second data line 1022.

In the sector 10b, the spacing between the first data line 1021 and the third data line 1023, the spacing between the third data line 1023 and the second data line 1022, and the spacing between the second data line 1022 and the fourth data line 1024 are equal to each other.

In an area between the display area 10a and the sector area 10b, one of the second data line 1022 and the third data line 1023 includes a first trace section 10231 and a second trace section 10232, the second trace section 10232 and the first trace section 10231 are located in different metal layers and are electrically connected, the other of the second data line 1022 and the third data line 1023 includes a third trace section 10221, the third trace section 10221 and the second trace section 10232 are located in different metal layers, and the third trace section 10221 and the second trace section 10232 are electrically insulated and intersected. In a thickness direction of the display panel 10, the second trace section 10232 and the third trace section 10221 are respectively located on opposite sides of the first trace section 10231, so as to minimize parasitic capacitance formed by front intersection between the second trace section 10232 and the third trace section 10221, and avoid a problem of uneven display caused by too large parasitic capacitance due to front intersection.

Specifically, the second data line 1022 includes a third trace section 10221 extending in a direction away from the first data line 1021, and the third trace section 10221 is parallel to the first direction. The third data line 1023 includes a first trace section 10231 and a second trace section 10232 which are located in different metal layers and are electrically connected. The third trace section 10221 and the second trace section 10232 are respectively located on opposite sides of the first trace section 10231. The first trace section 10231 extends in a direction close to the first data line 1021. The first trace section 10231 is parallel to the first direction, and the second trace section 10232 is parallel to the second direction.

It can be understood that the second data line 1022 may also include a first trace section 10231 and a second trace section 10232 located in different metal layers and electrically connected, and the third data line 1023 includes a third trace section 10221.

The display panel further includes a substrate 11, and the third trace section 10221 is located between the first trace section 10231 and the substrate 11.

In the thickness direction of the display panel 10, the first data line 1021 and the second data line 1022 in the sector 10b are located in the same layer and are made of the same material, and the third data line 1023 and the fourth data line 1024 in the sector 10b are located in the same layer and are made of the same material, so as to facilitate arrangement of wirings in the sector 10b using different metal layers, thus reducing risk of forming short circuit between the data lines in the sector 10b.

In the display area 10a, the first data line 1021, the second data line 1022, the third data line 1023, and the fourth data line 1024 are disposed in the same layer and are made of the same material, so as to simplify the manufacturing process.

In the thickness direction of the display panel 10, the first data line 1021, the second data line 1022, the third data line 1023, and the fourth data line 1024 in the display area 10a are located on one side of the second trace section 10232 away from the substrate 11.

As shown in FIG. 5, the display panel 10 includes a substrate 11, a buffer layer 12, a first semiconductor layer 13, a first insulating layer 14, a first conductive layer 15, a second insulating layer 16, a second conductive layer 17, a third insulating layer 18, a second semiconductor layer 19, a fourth insulating layer 21, a third conductive layer 22, a fifth insulating layer 23, a fourth conductive layer 24, a first planarization layer 25, a fifth conductive layer 26, a second planarization layer 27, a first electrode layer 28, a pixel definition layer 29, an organic light-emitting layer 31, and a second electrode layer 32, which are sequentially stacked.

All of the buffer layer 12, the first insulating layer 14, the second insulating layer 16, the third insulating layer 18, the fourth insulating layer 21, and the fifth insulating layer 23 have an inorganic film layer, and both the first planarization layer 25 and the second planarization layer 27 have an organic film layer with a thickness of 1 micron to 3 microns.

The first data line 1021, the second data line 1022, the third data line 1023, and the fourth data line 1024 in the display area 10a are all located in the fifth conductive layer 26. The first data line 1021 and the second data line 1022 in the sector 10b, and the third trace section 10221 of the second data line 1022 located between the sector 10b and the display area 10a are located in the first conductive layer 15. The third data line 1023 and the fourth data line 1024 in the sector 10b, and the first trace section 10231 of the third data line 1023 located between the sector 10b and the display area 10a are located in the second conductive layer 17. The second trace section 10232 of the third data line 1023 located between the sector 10b and the display area 10a is located in the fourth conductive layer 24.

The following description describes a planar layout of the second pixel circuit 1013 and signal lines electrically connected to the second pixel circuit 1013 in FIG. 4 with reference to specific film stack structure of the display panel shown in FIG. 5. According to principle of mirror symmetry, planar layouts of the third pixel circuit 1014, the first pixel circuit 1012, and the fourth pixel circuit 1015 can be known.

The first semiconductor layer 13 is an active layer forming the first transistor T1, the second transistor T2, the fifth transistor T5, the sixth transistor T6, and the seventh transistor T7. A material for preparing the first semiconductor layer 13 is low-temperature polysilicon.

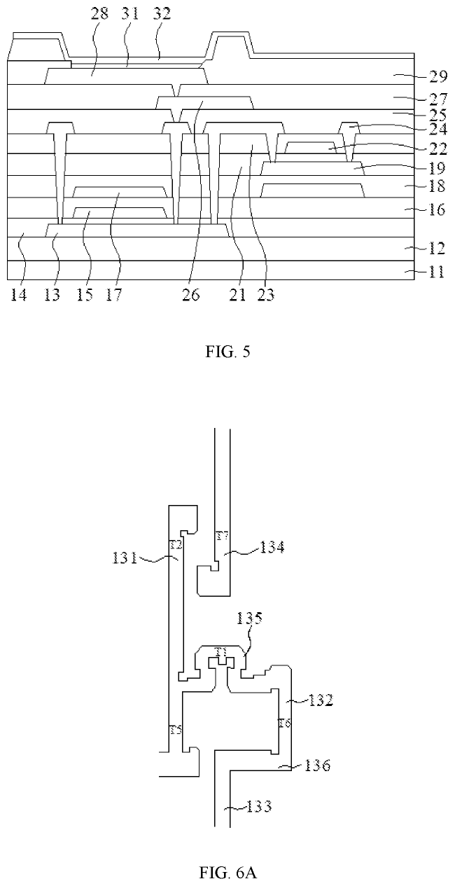

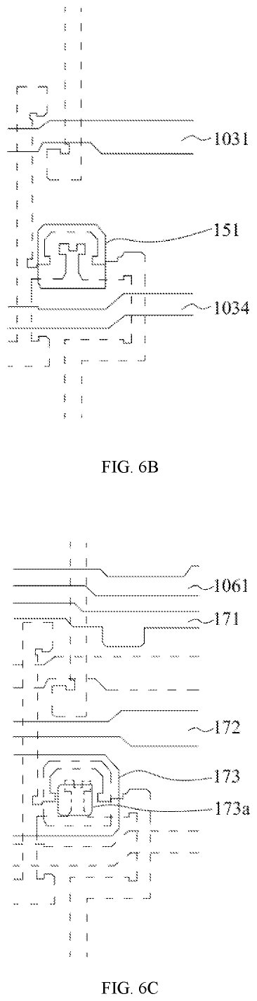

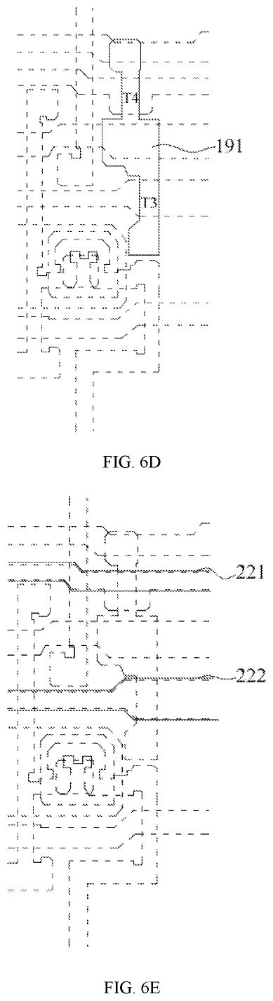

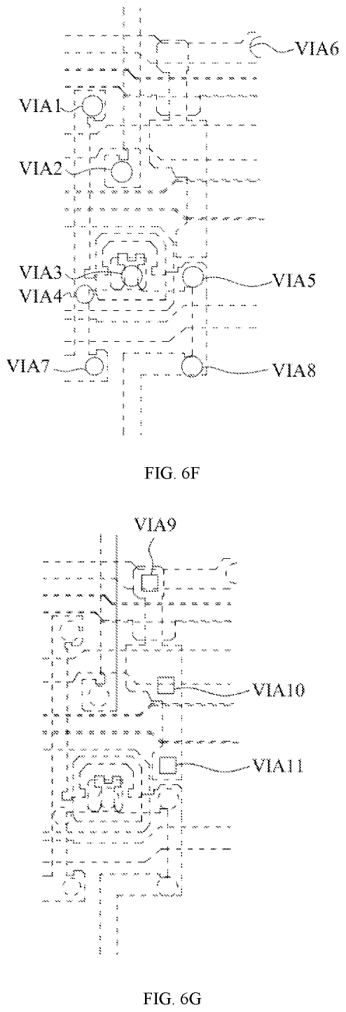

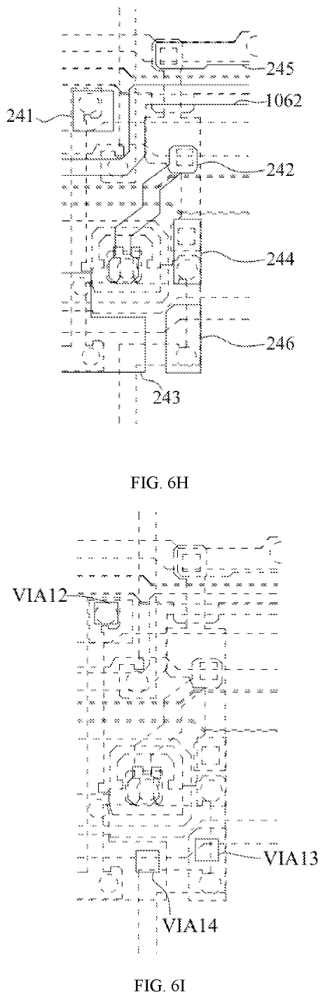

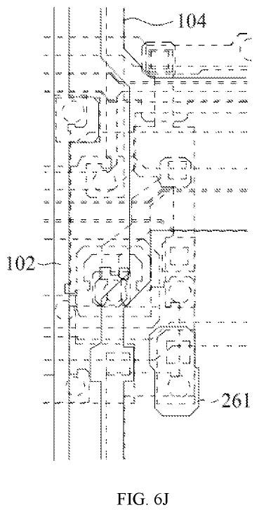

As shown in FIG. 6A, the first semiconductor layer 13 includes a first vertical portion 131, a second vertical portion 132, a third vertical portion 133, a fourth vertical portion 134, a first horizontal extension portion 135, and a second horizontal extension portion 136. The first vertical portion 131, the second vertical portion 132, the third vertical portion 133, and the fourth vertical portion 134 extend substantially along the column direction. The first horizontal extension 135 and the second horizontal extension 136 extend substantially along the row direction.

The first horizontal extension portion 135 is connected between the first vertical portion 131 and the second vertical portion 132, the second vertical portion 132 is connected between the first horizontal extension portion 135 and the second horizontal extension portion 136, and the third vertical portion 133 is connected to one side of the second horizontal extension portion 136 away from the second vertical portion 132. The fourth vertical portion 134 is separated from the first vertical portion 131, the second vertical portion 132, the third vertical portion 133, the first horizontal extension portion 135, and the second horizontal extension portion 136. The first vertical portion 131 and the second vertical portion 132 are located at opposite edges of the pixel circuit, and the fourth vertical portion 134 is disposed adjacent to the first vertical portion 131.

The first horizontal extension portion 135 includes a channel of the first transistor T1, the first vertical portion 131 includes a channel of the second transistor T2 and a channel of the fifth transistor T5, the second vertical portion 132 includes a channel of the sixth transistor T6, and the fourth vertical portion 134 includes a channel of the seventh transistor T7.

As shown in FIG. 6B, the first conductive layer 15 includes a first scanning signal line 1031, a gate 151 of the first transistor T1, and a light-emitting control signal line 1034. Both the first scanning signal line 1031 and the light-emitting control signal line 1034 extend along the row direction, and the gate 151 of the first transistor T1 is located between the first scanning signal line 1031 and the light-emitting control signal line 1034.

The first scanning signal line 1031 includes a gate of the second transistor T2 and a gate of the seventh transistor T7. The light-emitting control signal line 1034 includes a gate of the fifth transistor T5 and a gate of the sixth transistor T6.

The gate 151 of the first transistor T1 overlaps the first horizontal extension portion 135. The first scanning signal line 1031 intersects with the first vertical portion 131 and the fourth vertical portion 134. The light-emitting control signal line 1034 intersects with the first vertical portion 131 and the second vertical portion 132.

As shown in FIG. 6C, the second conductive layer 17 includes a first initialization voltage line 1061, a third lower scanning signal line 171, a second lower scanning signal line 172, and a second electrode plate 173. The first initialization voltage line 1061, the third lower scanning signal line 171, and the second lower scanning signal line 172 all extend in the row direction, and the third lower scanning signal line 171 is located between the first initialization voltage line 1061 and the second lower scanning signal line 172. The second electrode plate 173 is located on one side of the second lower scanning signal line 172 away from the third lower scanning signal line 171.

The third lower scanning signal line 171 includes a lower gate of the fourth transistor T4, and the second lower scanning signal line 172 includes a lower gate of the third transistor T3.

The first initialization voltage line 1061 and the third lower scanning signal line 171 intersect with the fourth vertical portion 134. The second lower scanning signal line 172 intersects with the first vertical portion 131.

The second electrode plate 173 overlaps the gate 151 of the first transistor T1, and the gate 151 of the first transistor T1 is the first electrode plate of the first capacitor C1. An intermediate position of the second electrode plate 173 includes an opening 173a.

As shown in FIG. 6D, the second semiconductor layer 19 is an active layer forming the third transistor T3 and the fourth transistor T4. A preparation material of the second semiconductor layer 19 is a metal oxide including indium gallium zinc oxide.

The second semiconductor layer 19 includes a fifth vertical portion 191 extending in the column direction. The fifth vertical portion 191 includes a channel of the third transistor T3 and a channel of the fourth transistor T4.

The fifth vertical portion 191 intersects with the third lower scanning signal line 171 and the second lower scanning signal line 172. The fifth vertical portion 191 intersects with the first scanning signal line 1031, a portion where the fifth vertical portion 191 overlaps the first scanning signal line 1031 is the third electrode plate of the second capacitor C2, and a portion where the first scanning signal line 1031 overlaps the fifth vertical portion 191 is the fourth electrode plate of the second capacitor C2.

As shown in FIG. 6E, the third conductive layer 22 includes a third upper scanning signal line 221 and a second upper scanning signal line 222, and both the third upper scanning signal line 221 and the second upper scanning signal line 222 extend along the row direction.

The third upper scanning signal line 221 disposed corresponding to the third lower scanning signal line 171, and the third upper scanning signal line 221 overlaps the third lower scanning signal line 171. The third upper scanning signal line 221 is electrically connected to the corresponding third lower scanning signal line 171, and the third upper scanning signal line 221 and the corresponding third lower scanning signal line 171 together form the third scanning signal line 1033.

The second upper scanning signal line 222 is disposed corresponding to the second lower scanning signal line 172, and the second upper scanning signal line 222 overlaps the second lower scanning signal line 172. The second upper scanning signal line 222 is electrically connected to the corresponding second lower scanning signal line 172, and the second upper scanning signal line 222 and the corresponding second lower scanning signal line 172 together form the second scanning signal line 1032.

The third upper scanning signal line 221 includes an upper gate of the fourth transistor T4, and the second upper scanning signal line 222 includes an upper gate of the third transistor T3.

Both the third upper scanning signal line 221 and the second upper scanning signal line 222 intersect with the fifth vertical portion 191.

As shown in FIG. 6F, the display panel 10 includes contact holes from a first contact hole VIA1 to an eighth contact hole VIA8 for overlapping the fourth conductive layer 24 with at least one of the first semiconductor layer 13, the first conductive layer 15 and the second conductive layer 17.

The first contact hole VIA1 exposes a portion of the first vertical portion 131. The first electrode of the second transistor T2 and a first lead 241 of the fourth conductive layer 24 which will be mentioned below are electrically connected through the first contact hole VIA1. The first contact hole VIA1 penetrates through the first insulating layer 14 to the fifth insulating layer 23.

The second contact hole VIA2 exposes a portion of the fourth vertical portion 134. The second electrode of the seventh transistor T7 and a second initialization voltage line 1062 of the fourth conductive layer 24 which will be mentioned below are electrically connected through the second contact hole VIA2. The second contact hole VIA2 penetrates through the first insulating layer 14 to the fifth insulating layer 23.

The third contact hole VIA3 is disposed corresponding to the opening 173a. The gate 151 of the first transistor T1 and a second lead 242 in the fourth conductive layer 24 which will be mentioned below are electrically connected through the third contact hole VIA3 and the opening 173a. The third contact hole VIA3 penetrates through the first insulating layer 14 to the fifth insulating layer 23.

The fourth contact hole VI4 exposes a portion of the second electrode plate 173. The second electrode plate 173 and a third lead 243 in the fourth conductive layer 24 which will be mentioned below are electrically connected through the fourth contact hole VI4. The third lead 243 transmits the first power supply voltage VDD, so that the second electrode plate 173 is connected to the first power supply voltage VDD. The fourth contact hole VI4 penetrates through the third insulating layer 18 to the fifth insulating layer 23.

The fifth contact hole VI5 exposes a portion of the first horizontal extension portion 135. The second electrode of the first transistor T1 and a fourth lead 244 in the fourth conductive layer 24 which will be mentioned below are electrically connected through the fifth contact hole VI5. The fifth contact hole VI5 penetrates through the first insulating layer 14 to the fifth insulating layer 23.

The sixth contact hole VI6 exposes a portion of the first initialization voltage line 1061. The first initialization voltage line 1061 and a fifth lead 245 in the fourth conductive layer 24 which will be mentioned below are electrically connected through the sixth contact hole VI6 to transmit the first initialization voltage Vi1 transmitted by the first initialization voltage line 1061 to the fifth lead 245. The sixth contact hole VI6 penetrates through the second insulating layer 16 to the fifth insulating layer 23.

The seventh contact hole VI7 exposes a portion of the first vertical portion 131. The first electrode of the fifth transistor T5 and a third lead 243 in the fourth conductive layer which will be mentioned below are electrically connected through the seventh contact hole VI7, so that the first electrode of the fifth transistor T5 is connected to the first supply voltage VDD. The seventh contact hole VI7 penetrates through the first insulating layer 14 to the fifth insulating layer 23.

The eighth contact hole VI8 exposes a portion of the second horizontal extension portion 136. The second electrode of the sixth transistor T6 and a sixth lead 246 in the fourth conductive layer 24 which will be mentioned below are electrically connected through the eighth contact hole VI8.

As shown in FIG. 6G, the display panel 10 includes contact holes from a ninth contact hole VIA9 to an eleventh contact hole VIA11 for overlapping the fourth conductive layer 24 with the second semiconductor layer 19.

The ninth contact hole VIA9 exposes the fifth vertical portion 191. The second electrode of the fourth transistor T4 and a second initialization voltage line 1062 in the fourth conductive layer 24 which will be mentioned below are electrically connected through the ninth contact hole VIA9.

The tenth contact hole VIA10 exposes the fifth vertical portion 191. A second lead 242 in the fourth conductive layer 24 which will be mentioned below is electrically connected to the first electrode of the fourth transistor T4 and the first electrode of the third transistor T3 through the tenth contact hole VIA10, so that the second lead 242 bridges the gate 151 of the first transistor T1 and the first electrode of the fourth transistor T4 and the first electrode of the third transistor T3.

The eleventh contact hole VIA11 exposes the fifth vertical portion 191. A fourth lead 244 in the fourth conductive layer 24 which will be mentioned below is electrically connected through the eleventh contact hole VIA11, so that the fourth lead 244 bridges the second electrode of the first transistor T1 and the second electrode of the third transistor T3.

As shown in FIG. 6H, the fourth conductive layer 24 includes leads from a first lead 241 to a sixth lead 246 and a second initialization voltage line 1062.

The second initialization voltage line 1062 extends along the row direction and intersects with the fourth vertical portion 134, the first vertical portion 131, and the fifth vertical portion 191.

The first lead 241 overlaps the first vertical portion 131. The second lead 242 is disposed obliquely, one end of the second lead 242 overlaps the fifth vertical portion 191, the other end of the second lead 242 overlaps the gate of the first transistor T1, and one end of the second lead 242 is disposed opposite to the other end of the second lead 242. The third lead 243 has an L-shaped block shape, and overlaps the second electrode plate 173 and the first vertical portion 131. The fourth lead 244 overlaps the fifth vertical portion 191 and the first horizontal extension portion 135. The fifth lead 245 overlaps the first initialization voltage line 1061. The sixth lead 246 overlaps the second horizontal extension portion 136.

As shown in FIG. 6I, the first planarization layer 25 includes contact holes from a twelfth contact hole VIA12 to a fourteenth contact hole VIA14 for overlapping the fourth conductive layer 24 and the fifth conductive layer 26.

The twelfth contact hole VIA12 is disposed to overlap the first lead 241. The twelfth contact hole VIA12 is used to electrically connect the first lead 241 and the data line 102 of the fifth conductive layer 26 which will be mentioned below, so that the first electrode of the second transistor T2 is electrically connected to the data line 102.

The thirteenth contact hole VIA13 is disposed to overlap the sixth lead 246. The thirteenth contact hole VIA13 is used to electrically connect the sixth lead 246 and the seventh lead 261 of the fifth conductive layer 26 which will be mentioned below, so that the seventh lead 261 is electrically connected to the second electrode of the sixth transistor T6.

The fourteenth contact hole VIA14 is disposed to overlap the third lead 243. The fourteenth contact hole VIA14 is used to electrically connect the third lead 243 and the first power supply voltage line 104 which will be mentioned below, so that the third lead 243 is input with the first power supply voltage VDD.

As shown in FIG. 6J, the fifth conductive layer includes a first power supply voltage line 104, a data line 102, and a seventh lead 261. Both the first power supply voltage line 104 and the data line 102 extend along the column direction.

The data line 102 overlaps the first vertical portion 131. The first power supply voltage line 104 overlaps the fifth vertical portion 191, the third lead 243, and the like. The seventh lead 261 is disposed to overlap the sixth lead 246.

The description of the above embodiments is merely intended to help understand the technical solutions and core ideas of the present disclosure. A person skilled in the art shall understand that it is possible to modify the technical solutions described in the foregoing embodiments, or to equivalently substitute some of the technical features thereof. These modifications or substitutions do not depart the nature of the corresponding technical solutions from the technical solutions in embodiments of the present disclosure.

What is claimed is:

1. A display panel, wherein the display panel includes a display area and a binding area, and the display panel comprises:
a first data line, a second data line and a third data line extending from the display area to the binding area; a first pad, a second pad and a third pad disposed in the binding area; and a source driver chip;
wherein in the display area, the first data line is electrically connected to a first column of sub-pixels of the display area; the second data line is electrically connected to a second column of sub-pixels; the third data line is electrically connected to a third column of sub-pixels; the second data line is located between the first data line and the third data line, and a spacing between the first data line and the second data line is less than a spacing between the third data line and the second data line; the second column of sub-pixels is located between the first column of sub-pixels and the third column of sub-pixels; and
wherein the source driver chip is connected to the first pad, the second pad, and the third pad.

2. The display panel according to claim 1, wherein the first pad is located on one side of the second data line and the third data line close to the first data line, and the first pad is electrically connected to the first data line;
the second pad is electrically connected to the third data line;
the third pad is electrically connected to the second data line, wherein the second pad is located between the first pad and the third pad in a second direction.

3. The display panel according to claim 1, wherein the display panel further includes a sector area located between the display area and the binding area;
the third data line intersects the second data line in an area between the sector area and the display area; and
in the sector, the third data line is located between the second data line and the first data line.

4. The display panel according to claim 1, wherein in the display area, the display panel further comprises a first pixel circuit, a second pixel circuit and a third pixel circuit;
the first pixel circuit located is electrically connected to the first data line;
the second pixel circuit is electrically connected to the second data line; and
the third pixel circuit located is electrically connected to the third data line.

5. The display panel according to claim 1, wherein in the display area, at least a portion of the first pixel circuit is located on one side of the first data line away from the second data line, and at least a portion of the second pixel circuit and at least a portion of the third pixel circuit are located between the second data line and the third data line.

6. The display panel according to claim 1, wherein in an area between the display area and the sector area, one of the second data line and the third data line comprises a first trace section and a second trace section, the second trace section and the first trace section are located in different metal layers and are electrically connected, another of the second data line and the third data line comprises a third trace section, the third trace section and the second trace section are located in different metal layers, and the third trace section and the second trace section are electrically insulated and intersected; and
wherein, in a thickness direction of the display panel, the second trace section and the third trace section are respectively located on opposite sides of the first trace section.

7. The display panel according to claim 6, wherein the display panel further comprises a substrate, and the third trace section is located between the first trace section and the substrate.

8. The display panel according to claim 7, wherein the display panel further comprises:
a fourth data line extending from the display area to the binding area, wherein the fourth data line is electrically connected to a fourth column of sub-pixels of the display area, the fourth column of sub-pixels is located on one side of the third column of sub-pixels away from the second column of sub-pixels, and a spacing between the fourth data line and the third data line in the display area is less than a spacing between the third data line and the second data line.

9. The display panel according to claim 8, wherein the display panel further comprises a fourth pad disposed in the binding area and located on one side of the third pad away from the second pad, wherein the fourth pad is electrically connected to the fourth data line and is connected to the source driver chip.

10. The display panel according to claim 8, wherein in a thickness direction of the display panel, the first data line and the second data line in the sector are located in a same layer and are made of a same material; and the third data line and the fourth data line in the sector are located in a same layer and are made of a same material.

11. The display panel according to claim 8, wherein in the display area, the first data line, the second data line, the third data line, and the fourth data line are disposed in a same layer and prepared from a same material.

12. The display panel according to claim 8, wherein in a thickness direction of the display panel, the first data line, the second data line, the third data line, and the fourth data line located in the display area are located on one side of the second trace section away from the substrate.

13. The display panel according to claim 1, wherein in the sector area, a spacing between the first data line and the third data line is equal to a spacing between the third data line and the second data line.

14. The display panel according to claim 4, wherein in the display area, the first pixel circuit and the second pixel circuit are disposed symmetrically about a center line between the first data line and the second data line, and the second pixel circuit and the third pixel circuit are disposed symmetrically about a center line between the second data line and the third data line.

15. The display panel according to claim 4, wherein the second pixel circuit and the third pixel circuit share a power supply signal line, and the power supply signal line shared by the second pixel circuit and the third pixel circuit is located between the second data line and the third data line.

16. The display panel according to claim 1, wherein the display panel further comprises a plurality of sub-pixels, a first scanning signal line, a second scanning signal line, a third scanning signal line, a light-emitting control signal line, a first power supply voltage line, a second power supply voltage line, a first initialization voltage line and a second initialization voltage line, and wherein the plurality of sub-pixels are arrayed in the display area of the display panel along a row direction and a column direction.

17. The display panel according to claim 16, wherein the display panel further comprises a gate driver circuit, and the gate driver circuit is electrically connected to the first scanning signal line, the second scanning signal line, and the third scanning signal line to output a first scanning signal, a second scanning signal and a third scanning signal, respectively.

18. The display panel according to claim 16, wherein the display panel further comprises a light-emitting control driver circuit, and the light-emitting control driver circuit is connected to the light-emitting control signal line to output a light-emitting control signal.

19. The display panel according to claim 16, wherein a plurality of the first power supply voltage lines are disposed in the display area and extend along the second direction, and one of the plurality of the first power supply voltage lines is disposed between two adjacent ones of the data lines.

20. The display panel according to claim 16, wherein each of the plurality of sub-pixels comprises a pixel circuit, and the pixel circuit comprises an organic light-emitting diode, a plurality of transistors, and capacitors.
